(19) United States
(12) Patent Application Publication
(10) Pub. No.: US 2024/0237339 A1
(43) Pub. Date: Jul. 11, 2024

(54) SEMICONDUCTOR STRUCTURE AND METHOD FOR MANUFACTURING THE SAME

(71) Applicant: MACRONIX INTERNATIONAL CO., LTD., Hsinchu (TW)

(72) Inventors: Ting-Feng LIAO, Hsin-chu (TW); Kuang-Wen LIU, Hsin-chu (TW)

(21) Appl. No.: 18/150,211

(22) Filed: Jan. 5, 2023

(51) Int. Cl. H10B 43/27; H01L 23/528; H10B 41/10; H10B 41/27; H10B 41/40; H10B 43/10; H10B 43/40

(52) U.S. Cl. CPC H10B 43/27; H01L 23/5283; H10B 41/10; H10B 41/27; H10B 41/40; H10B 43/10; H10B 43/40

(57) ABSTRACT

A semiconductor structure is provided. The semiconductor structure has a device region and a periphery region adjacent to the device region. The periphery region comprises an array contact defining region and a periphery contact defining region. The semiconductor structure comprises a substrate, a staircase structure, an etch stop layer, a plurality of array contacts, and a plurality of periphery contacts. The staircase structure is disposed on the substrate in the periphery region. The staircase structure comprises conductive layers and dielectric layers disposed alternately. The etch stop layer is disposed on the staircase structure in the array contact defining region. The array contacts are disposed on the staircase structure and through the etch stop layer in the array contact defining region. The periphery contacts are through the staircase structure in the periphery contact defining region.

### TECHNICAL FIELD

This disclosure relates to a semiconductor structure and a method for manufacturing the same. More particularly, this disclosure relates to a semiconductor structure comprising array contacts and periphery contacts formed by common processes and a method for manufacturing the same.

### BACKGROUND

Cost has always been an important issue in manufacturing industries. For example, deep etch process is an expensive process among the semiconductor processes. In a periphery region of a 3D memory device, dummy active structures for supporting a high stacked structure, array contacts, and periphery contacts are typically formed individually by deep etch processes. In such a condition, the cost will increase as the number of layers in the stacked structure increases.

### SUMMARY

This disclosure is aimed at the reduction of cost by forming several components that must be manufactured using deep etch processes with common processes.

According to some embodiments, a semiconductor structure is provided. The semiconductor structure has a device region and a periphery region adjacent to the device region. The periphery region comprises an array contact defining region and a periphery contact defining region. The semiconductor structure comprises a substrate, a staircase structure, an etch stop layer, a plurality of array contacts, and a plurality of periphery contacts. The staircase structure is disposed on the substrate in the periphery region. The staircase structure comprises conductive layers and dielectric layers disposed alternately. The etch stop layer is disposed on the staircase structure in the array contact defining region. The array contacts are disposed on the staircase structure and through the etch stop layer in the array contact defining region. The periphery contacts are through the staircase structure in the periphery contact defining region.

According to some embodiments, a method for manufacturing a semiconductor structure is provided. The semiconductor structure has a device region and a periphery region adjacent to the device region. The periphery region comprises an array contact defining region and a periphery contact defining region. The method comprises the following steps. First, a partially formed structure is provided. The partially formed structure comprises a substrate and an initial staircase structure on the substrate in the periphery region. The initial staircase structure comprises sacrificial layers and dielectric layers disposed alternately. An etch stop layer is formed on the initial staircase structure in the array contact defining region. Then, the sacrificial layers of the initial staircase structure are replaced with conductive layers so as to form a staircase structure comprising the conductive layers and the dielectric layers disposed alternately. A plurality of array contacts are formed on the staircase structure and through the etch stop layer in the array contact defining region, and a plurality of periphery contacts are formed through the staircase structure in the periphery contact defining region.

### BRIEF DESCRIPTION OF THE DRAWINGS

FIGS. 1A-1D illustrate an exemplary semiconductor structure according to embodiments.

FIGS. 2A-2B to FIGS. 21A-21D illustrate various stages of an exemplary method for manufacturing a semiconductor structure according to embodiments.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The following description and the accompanying drawings are provided for illustrative only, and not intended to result in a limitation. For clarity, the elements may not be drawn to scale. In addition, some elements and/or reference numerals may be omitted from some drawings. It is contemplated that the elements and features of one embodiment can be beneficially incorporated in another embodiment without further recitation.

This disclosure provides a semiconductor structure. The semiconductor structure has a device region and a periphery region adjacent to the device region. The periphery region comprises an array contact defining region and a periphery contact defining region. The semiconductor structure comprises a substrate, a staircase structure, an etch stop layer, a plurality of array contacts, and a plurality of periphery contacts. The staircase structure is disposed on the substrate in the periphery region. The staircase structure comprises conductive layers and dielectric layers disposed alternately. The etch stop layer is disposed on the staircase structure in the array contact defining region. The array contacts are disposed on the staircase structure and through the etch stop layer in the array contact defining region. The periphery contacts are through the staircase structure in the periphery contact defining region.

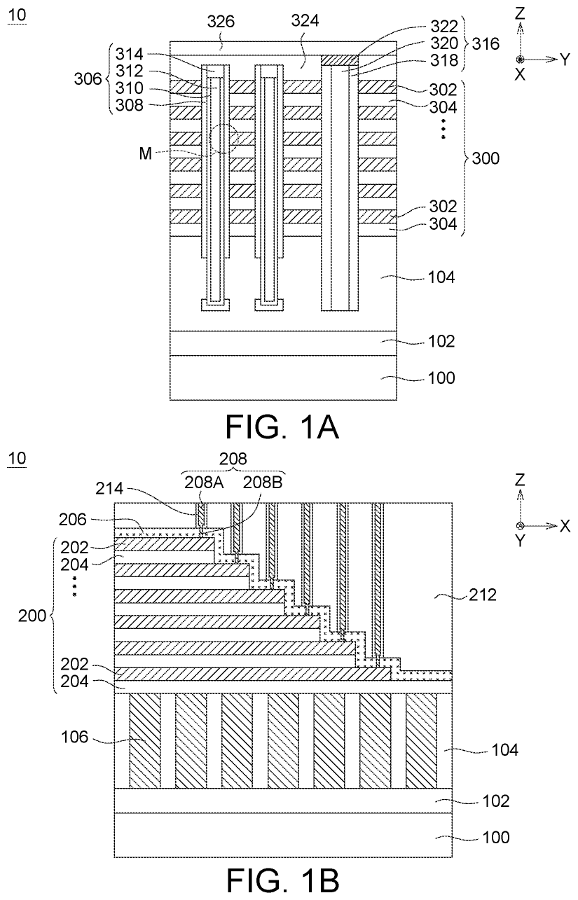

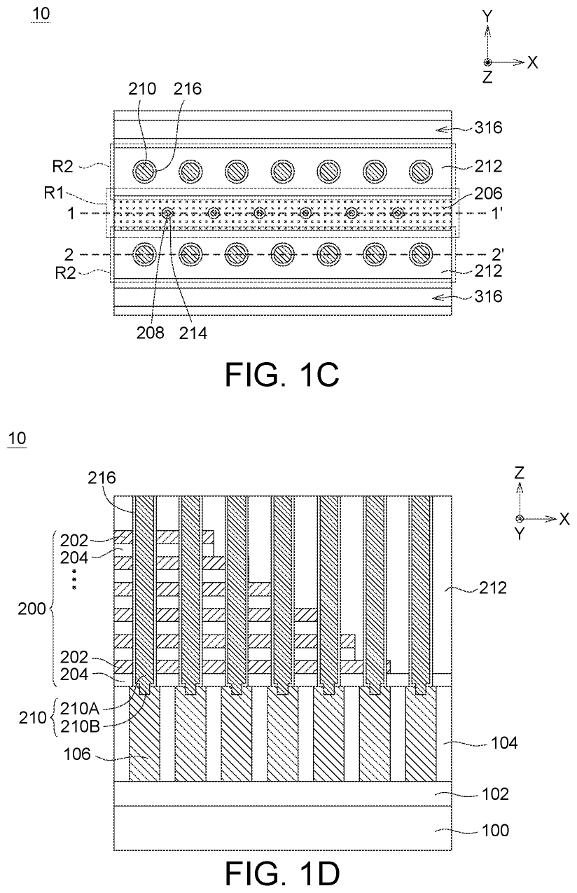

For more details, referring to FIGS. 1A-1D, an exemplary semiconductor structure 10 is illustrated, wherein FIG. 1A is a cross-sectional view of the device region, FIG. 1B is a cross-sectional view of the periphery region, FIG. 1C is a top view of the periphery region, FIG. 1D is another cross-sectional view of the periphery region, and FIG. 1B and FIG. 1D correspond to the line 1-1′ and the line 2-2′ in FIG. 1C, respectively.

The semiconductor structure 10 comprises a substrate 100. According to some embodiments, across the device region and the periphery region, the semiconductor structure 10 can further comprise a circuit layer 102 disposed on the substrate 100. The circuit layer 102 can comprise various electronic devices (not shown), such as but not limited to MOS devices and the like. According to some embodiments, the semiconductor structure 10 can further comprise a bottom conductive layer 104 disposed on the substrate 100. The bottom conductive layer 104 can be disposed on the circuit layer 102. According to some embodiments, the semiconductor structure 10 can further comprise a plurality of connectors 106 disposed on the circuit layer 102. The connectors 106 are connected to the circuit layer 102. More specifically, the connectors 106 are coupled to the electronic devices in the circuit layer 102.

This disclosure is focused on the periphery region of the semiconductor structure 10 as shown in FIGS. 1B-1D. The periphery region is adjacent to the device region. In some embodiments, the periphery region surrounds the device region. The periphery region comprises an array contact defining region R1 and a periphery contact defining region R2, and the cross-sectional view shown in FIGS. 1B and FIG. 1D correspond to the array contact defining region R1 and the periphery contact defining region R2, respectively. In some embodiments, the periphery contact defining region R2 comprises two separated regions, and the array contact defining region R1 is between the two separated regions.

In the periphery region, the semiconductor structure 10 comprises a staircase structure 200. The staircase structure 200 is disposed on the substrate 100. The staircase structure 200 can be disposed on the circuit layer 102 and/or the bottom conductive layer 104, if present. The staircase structure 200 comprises conductive layers 202 and dielectric layers 204 disposed alternately. Specifically, each stair of the staircase structure 200 comprises one conductive layer 202 and one dielectric layer 204. The conductive layers 202 can form treads of the staircase structure 200.

The semiconductor structure 10 comprises an etch stop layer 206 disposed on the staircase structure 200 in the array contact defining region R1. The etch stop layer 206 can be formed of a material which is non-conductive and selective with respect to polysilicon, nitride, and oxide during etching processes, such as carbon doped silicon nitride (sometimes also be referred to as SiCN). The etch stop layer 206 is beneficial for an accurate definition of array contacts on each stair.

The semiconductor structure 10 comprises a plurality of array contacts 208 and a plurality of periphery contacts 210. The array contacts 208 are disposed on the staircase structure 200 and through the etch stop layer 206 in the array contact defining region R1. Each of the array contacts 208 can stop on and be connected to the conductive layer 202 of the corresponding stair. Each of the array contacts 208 can have a first portion 208A and a second portion 208B under the first portion 208A, and a cross-sectional area of the second portion 208B is smaller than a cross-sectional area of the first portion 208A.

The periphery contacts 210 are through the staircase structure 200 in the periphery contact defining region R2. The periphery contacts 210 can be connected to the connectors 106 and further connected to the circuit layer 102 through the connectors 106. Each of the periphery contacts 210 can have a first portion 210A and a second portion 210B under the first portion 210A, and a cross-sectional area of the second portion 210B is smaller than a cross-sectional area of the first portion 210A. In this disclosure, the periphery contacts 210 also functions to support a high stacked structure, i.e., the staircase structure 200, instead of conventional dummy active structures.

In some embodiments, top surfaces of the array contacts 208 and top surfaces of the periphery contacts 210 can be flush. In some embodiments, each of the array contacts 208 can be surrounded by four periphery contacts 210 that are closest to the array contact 208 among the periphery contacts 210.

According to some embodiments, the semiconductor structure 10 can further comprise an interlayer dielectric layer 212 on the staircase structure 200 and the etch stop layer 206. The array contacts 208 and the periphery contacts 210 also through the interlayer dielectric layer 212. According to some embodiments, the semiconductor structure 10 can further comprise a plurality of first spacer layers 214 and a plurality of second spacer layers 216. The first spacer layers 214 surround the array contacts 208. The second spacer layers 216 surround the periphery contacts 210. More specifically, the first spacer layers 214 can completely cover sidewalls and bottom surfaces of the first portions 208A of the array contacts 208 and further extend to portions of sidewalls of the second portions 208B. The second spacer layers 216 can completely cover sidewalls and bottom surfaces of the first portions 210A of the periphery contacts 210 and further extend to portions of sidewalls of the second portions 210B.

Referring back to FIG. 1A, the configuration in the device region depends on the type of the semiconductor structure 10. For example, in the device region, the semiconductor structure 10 can comprise a memory array, and particularly a 3D memory array, such as a 3D NAND array or the like. Specifically, the semiconductor structure 10 can comprise a stack 300 disposed on the substrate 100 in the device region. The stack 300 comprises conductive layers 302 and dielectric layers 304 disposed alternately. It is understood that the staircase structure 200 disposed in the periphery region can be an extension of the stack 300. In some embodiments, the conductive layers 302 can comprise a high-k material, a barrier material, and a metal gate material.

The semiconductor structure 10 can comprise a plurality of active structures 306 through the stack 300. Each of the active structures 306 can comprises a memory layer 308, a channel layer 310, a dielectric material 312, and a contact 314. The memory layer 308 is formed as an outermost layer of the active structure 306. The channel layer 310 is disposed along the memory layer 308. The dielectric material 312 is disposed in a space defined by the channel layer 310. The contact 314 is disposed on the dielectric material 312. A plurality of memory cells M are defined by cross points of the conductive layers 302 in the stack 300 and the active structures 306.

The semiconductor structure 10 can further comprise a connecting structure 316 through the stack 300 and stop in the bottom conductive layer 104. The connecting structure 316 is electrically connected with the bottom conductive layer 104. In some embodiments, the memory layers 308 of the active structures 306 can have disconnections in the bottom conductive layer 104 such that the channel layers 310 of the active structures 306 are connected by the bottom conductive layer 104. As such, the connecting structure 316 can be coupled to the channel layers 310 through the bottom conductive layer 104. The connecting structure 316 can comprise a barrier layer 318, a conductive material 320, and a plug 322. The barrier layer 318 is formed as an outermost layer of the connecting structure 316. The conductive material 320 is disposed in a space defined by the barrier layer 318. The plug 322 is disposed on the conductive material 320.

According to some embodiments, the semiconductor structure 10 can further comprise a top interlayer dielectric layer 324 on the stack 300 and the active structures 306. According to some embodiments, the semiconductor structure 10 can further comprise another top interlayer dielectric layer 326 on the top interlayer dielectric layer 324 and the connecting structure 316.

This disclosure also provides a method for manufacturing a semiconductor structure. The semiconductor structure has a device region and a periphery region adjacent to the device region. The periphery region comprises an array contact defining region and a periphery contact defining region. The method comprises the following steps. First, a partially formed structure is provided. The partially formed structure comprises a substrate and an initial staircase structure on the substrate in the periphery region. The initial staircase structure comprises sacrificial layers and dielectric layers disposed alternately. An etch stop layer is formed on the initial staircase structure in the array contact defining region. Then, the sacrificial layers of the initial staircase structure are replaced with conductive layers so as to form a staircase structure comprising the conductive layers and the dielectric layers disposed alternately. A plurality of array contacts are formed on the staircase structure and through the etch stop layer in the array contact defining region, and a plurality of periphery contacts are formed through the staircase structure in the periphery contact defining region.

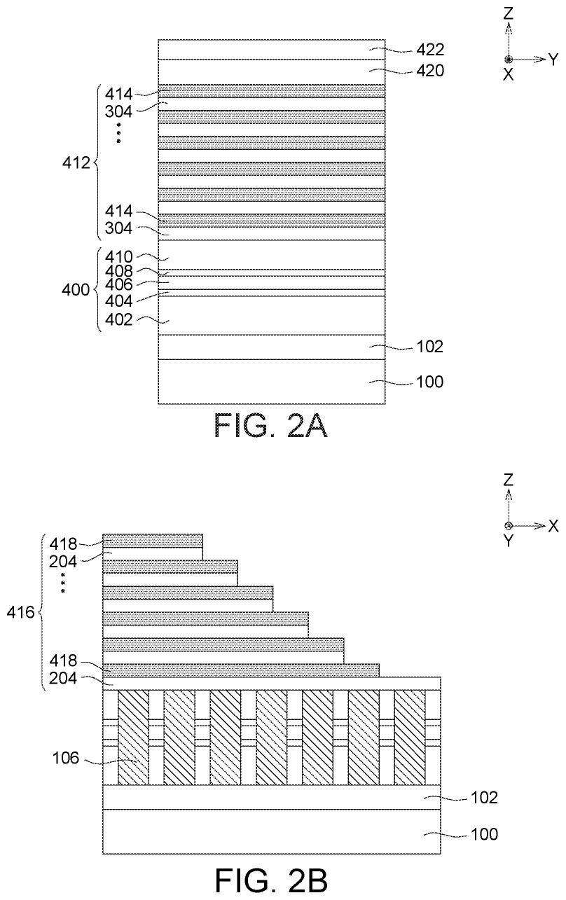

For more details, referring to FIGS. 2A-2B to FIGS. 21A-21D, various stages of an exemplary method for manufacturing the semiconductor structure 10 are illustrated, wherein the drawings identified by the same number are at the same stage, the drawings identified by “A” are cross-sectional views of the device region, the drawings identified by “B” are cross-sectional views of the periphery region, the drawings identified by “C”, if present, are top views of the periphery region, the drawings identified by “D”, if present, are another cross-sectional views of the periphery region, and the drawings identified by “B” and “D” correspond to the lines 1-1′ and the lines 2-2′ in the drawings identified by “C”, respectively.

As shown in FIGS. 2A-2B, a partially formed structure is provided. The partially formed structure comprises a substrate 100. The partially formed structure can further comprise a circuit layer 102 on the substrate 100. According to some embodiments, the partially formed structure can comprise a laminated structure 400 on the circuit layer 102. The laminated structure 400 comprises a first bottom etch stop layer 402, a first bottom dielectric layer 404, a bottom sacrificial layer 406, a second bottom dielectric layer 408, and a second bottom etch stop layer 410 disposed sequentially. The first bottom etch stop layer 402 can be formed of polysilicon. The first bottom dielectric layer 404 can be formed of oxide. The bottom sacrificial layer 406 can be formed of polysilicon. The second bottom dielectric layer 408 can be formed of oxide. The second bottom etch stop layer 410 can be formed of polysilicon. The partially formed structure can comprise a plurality of connectors 106 on the circuit layer 102 and through the laminated structure 400. The connectors 106 can be formed of tungsten.

The partially formed structure can further comprise an initial stack 412 on the substrate 100 in the device region. The initial stack 412 comprises sacrificial layers 414 and dielectric layers 304 disposed alternately. The partially formed structure comprises an initial staircase structure 416 on the substrate 100 in the periphery region. The initial staircase structure 416 comprises sacrificial layers 418 and dielectric layers 204 disposed alternately. Each stair of the initial staircase structure 416 comprises one sacrificial layer 418 and one dielectric layer 204. The sacrificial layers 418 form treads of the staircase structure 200. It is understood that the initial staircase structure 416 can be an extension of the initial stack 412. In such a case, the initial staircase structure 416 can be formed by a trim process for an extending portion of the initial stack 412 in the periphery region. The sacrificial layers 414 and 418 can be formed of silicon nitride. The dielectric layers 304 and 204 can be formed of oxide.

According to some embodiments, the partially formed structure can further comprise an interlayer dielectric material 420 on the initial stack 412. The interlayer dielectric material 420 can be oxide. According to some embodiments, the partially formed structure can comprise a sacrificial material 422 on the interlayer dielectric material 420. The sacrificial material 422 can be polysilicon.

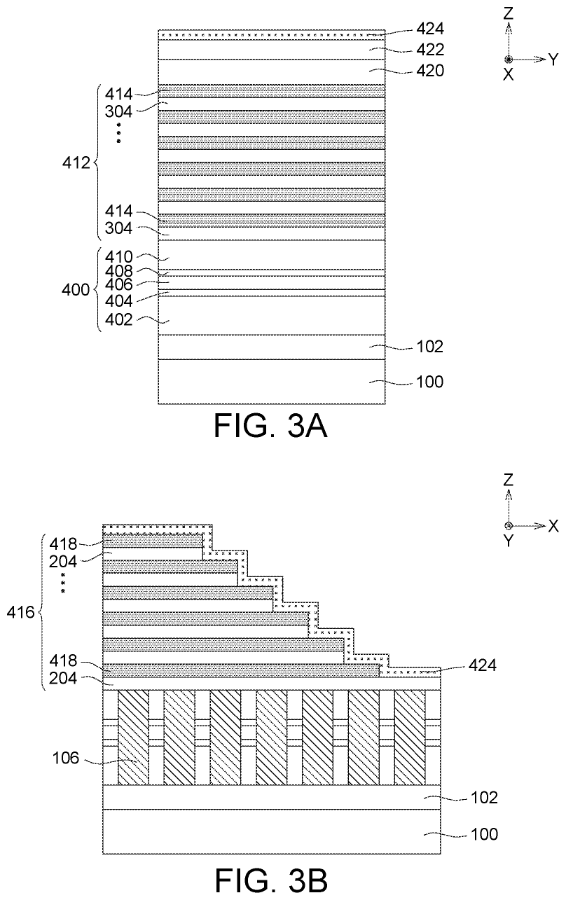

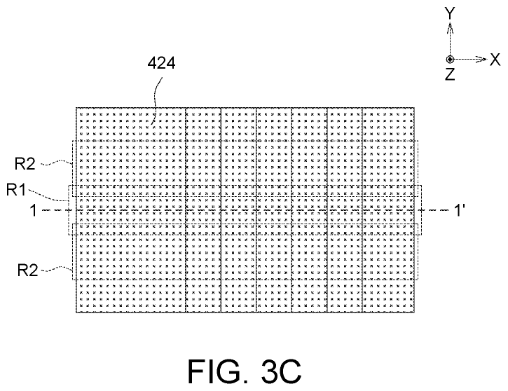

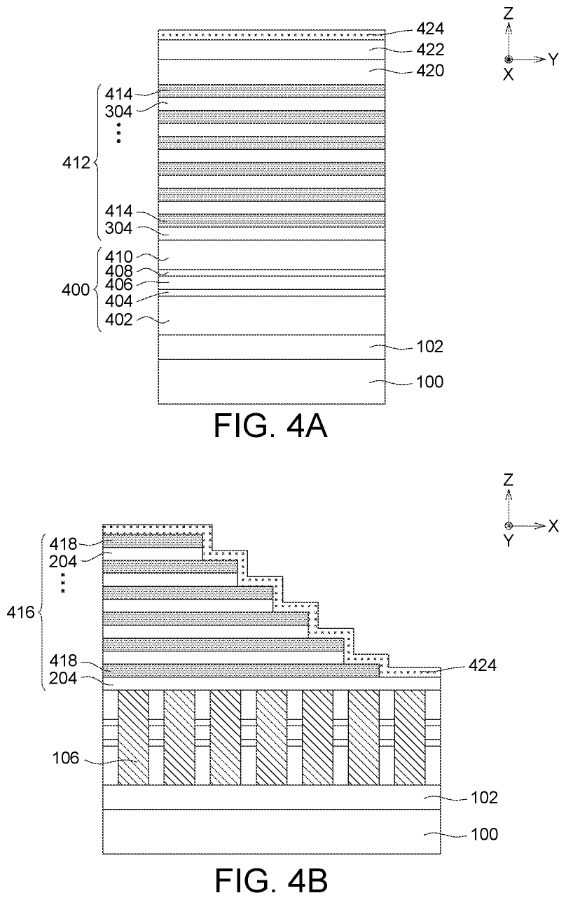

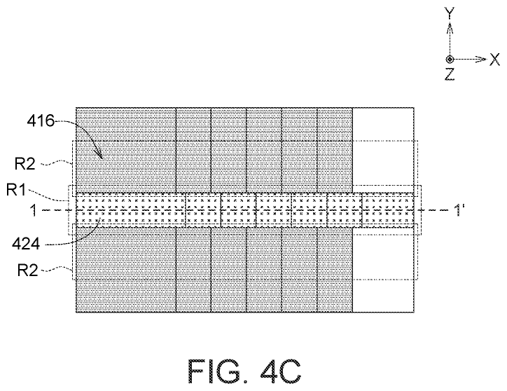

As shown in FIGS. 3A-3C, an etch sop material 424 is formed on the whole structure. The etch sop material 424 is non-conductive and selective with respect to polysilicon, nitride, and oxide during etching processes. For example, the etch sop material 424 can be carbon doped silicon nitride. Then, as shown in FIGS. 4A-4C, the etch sop material 424 in the periphery region other than in the array contact defining region R1 is removed. The etch sop material 424 remained in the array contact defining region R1 forms an etch stop layer 206.

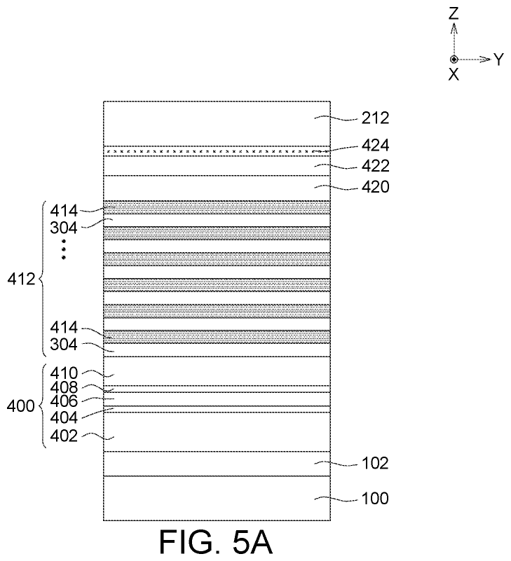

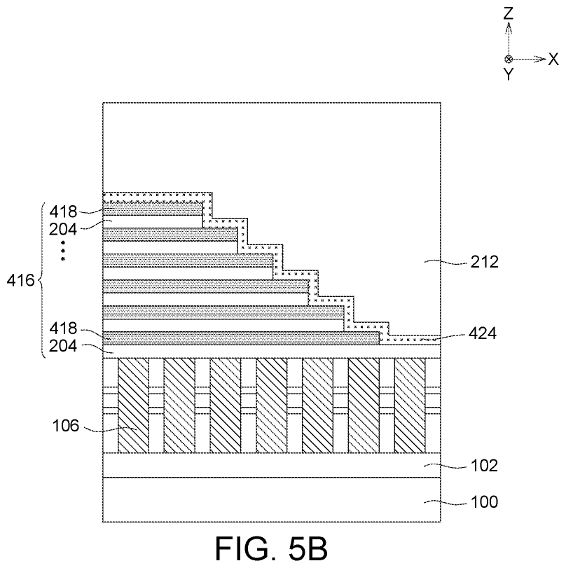

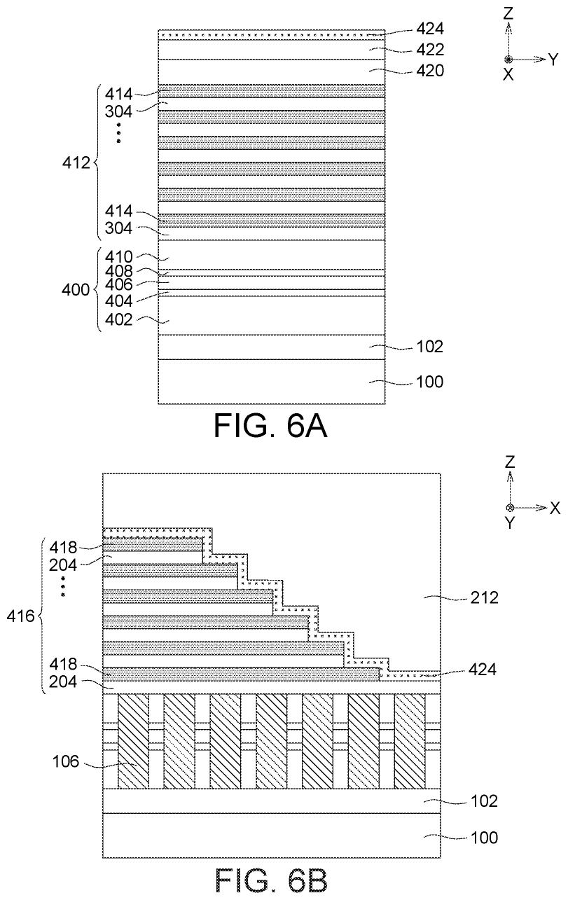

As shown in FIGS. 5A-5B, an interlayer dielectric layer 212 is formed on the initial staircase structure 416 and the etch stop layer 206. The interlayer dielectric layer 212 can be formed of oxide. In some embodiments, the interlayer dielectric layer 212 is also formed in the device region. Then, as shown in FIGS. 6A-6B, a portion of the interlayer dielectric layer 212 that is in the device region is removed by a planarization process, such as a CMP process, with the etch sop material 424 remained in the device region as a stop layer.

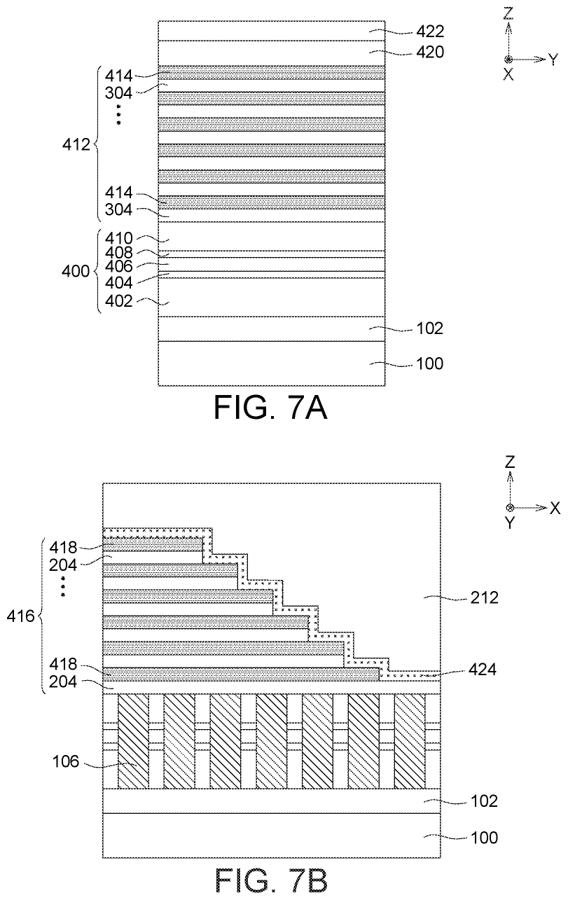

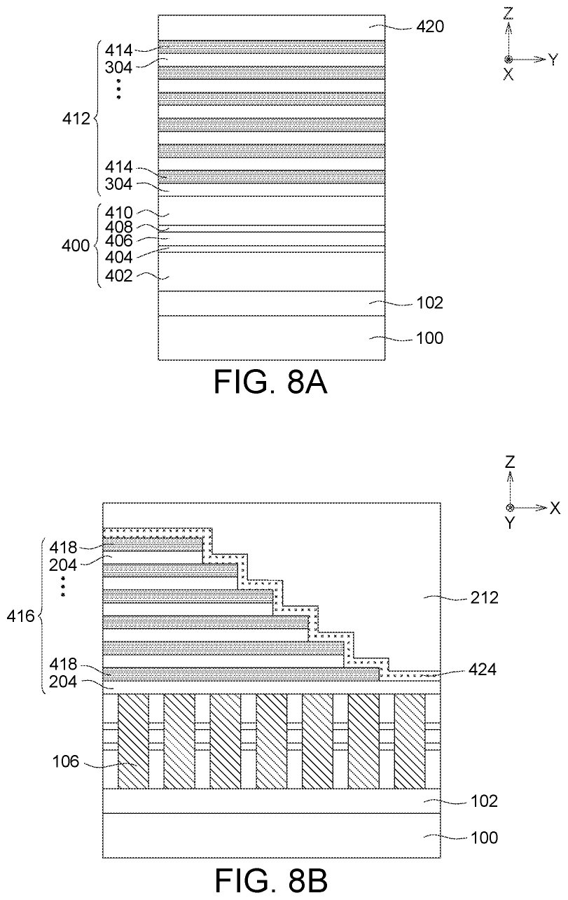

Thereafter, as shown in FIGS. 7A-7B, the etch sop material 424 remained in the device region is removed, such as by an etching process. Then, the sacrificial material 422 can be removed, as shown in FIGS. 8A-8B. A top portion of the interlayer dielectric layer 212 in the periphery region may also be removed, and the structures remained in the device region and the periphery region are flush. The removal as shown in FIGS. 8A-8B can be conducted by an etching process.

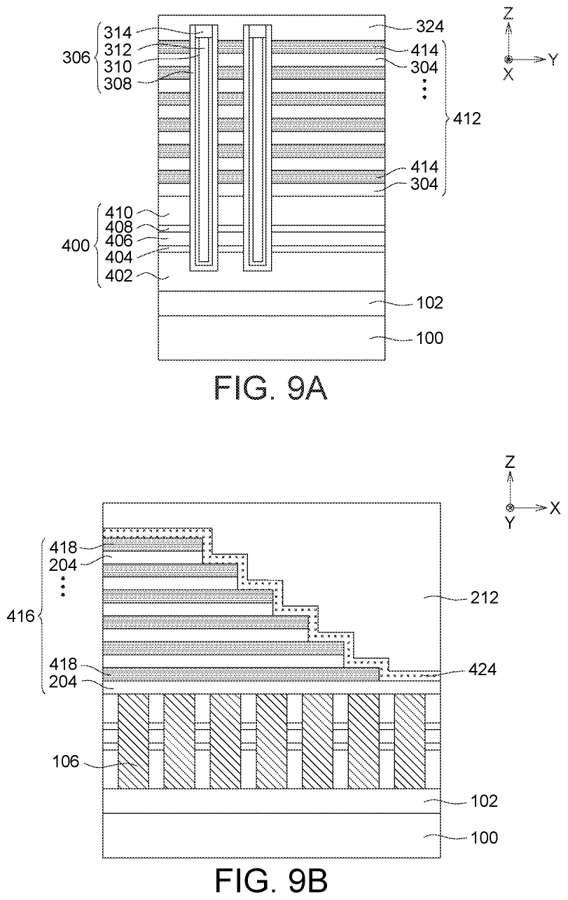

As shown in FIGS. 9A-9B, a plurality of active structures 306 are formed through the initial stack 412. Each of the active structures 306 can comprises a memory layer 308, a channel layer 310, a dielectric material 312, and a contact 314. The memory layer 308 is formed as an outermost layer of the active structure 306. The channel layer 310 is disposed along the memory layer 308. The dielectric material 312 is disposed in a space defined by the channel layer 310. The contact 314 is disposed on the dielectric material 312. In some embodiments, a portion of the interlayer dielectric material 420 is removed for the formation of the active structures 306, and then an additional interlayer dielectric material, such as oxide, is provided and covers the active structures 306. As such, a top interlayer dielectric layer 324 as shown in FIGS. 1A-1D is formed in the device region.

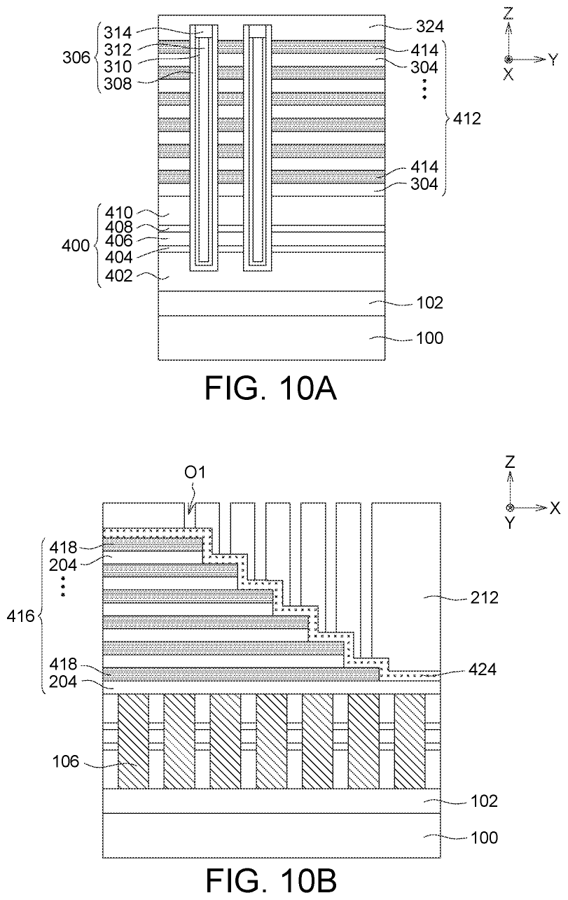

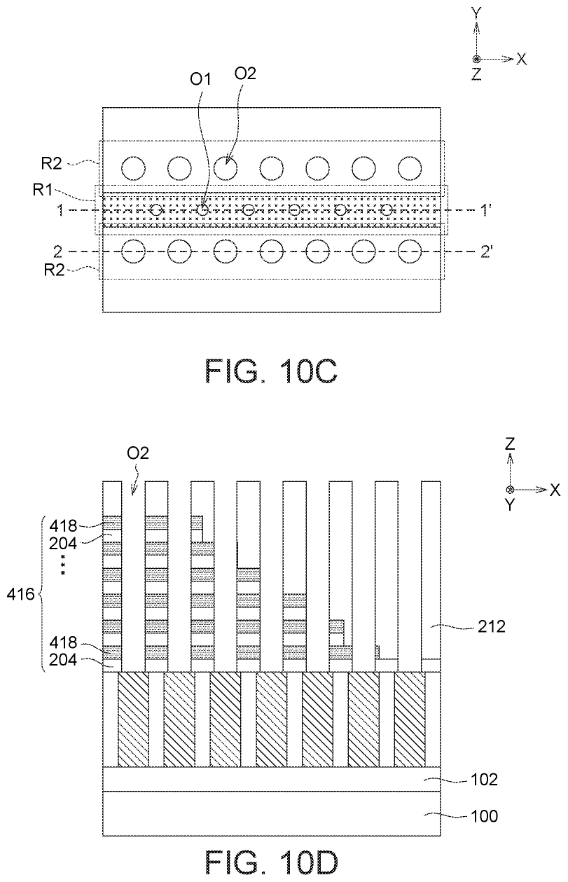

As shown in FIGS. 10A-10D, first openings O1 are formed through the interlayer dielectric layer 212 and the etch stop layer 206 and landing on stairs of the initial staircase structure 416, and second openings O2 are formed through the interlayer dielectric layer 212 and the initial staircase structure 416. The second openings O2 can land on the connectors 106 for the circuit layer 102. With the etch stop layer 206, the first openings O1 for the formation of array contacts 208 can stop on corresponding stairs accurately when the second openings O2 for the formation of periphery contacts 210 are stop on the connectors 106. As such, the formation of the array contacts 208 and the periphery contacts 210 can be conducted concurrently in the following processes. It should be noted that, the array contacts 208 cannot be formed concurrently with the deep periphery contacts 210 without the etch stop layer 206 since the first openings O1 for the array contacts 208, which have different heights, may be over-etched or misland when the second openings O2 for the deep periphery contacts 210 are formed at the same process. The arrangements of the first openings O1 and the second openings O2 depends on a predetermined arrangement for the array contacts 208 and the periphery contacts 210. For example, each of the first openings O1 can be surrounded by four second openings O2 that are closest to the first opening O1 among the second openings O2.

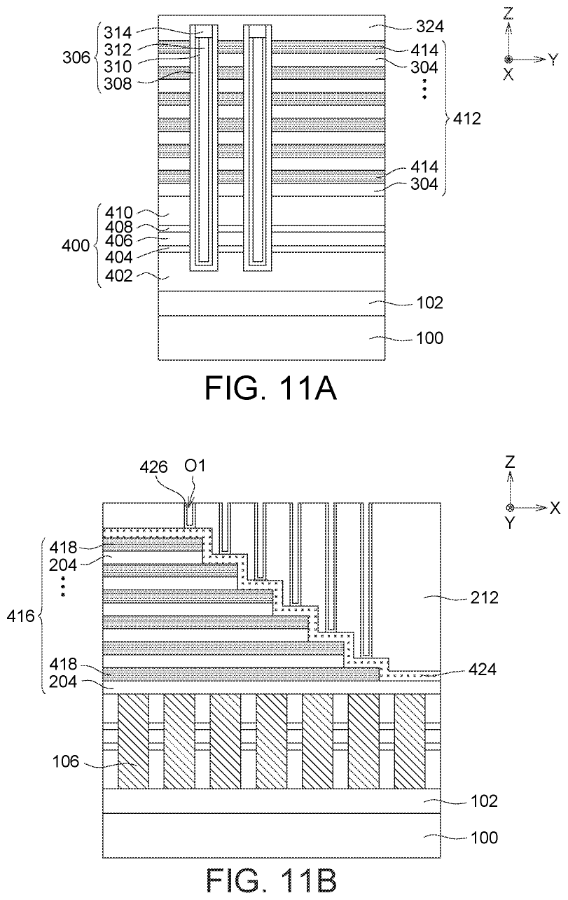

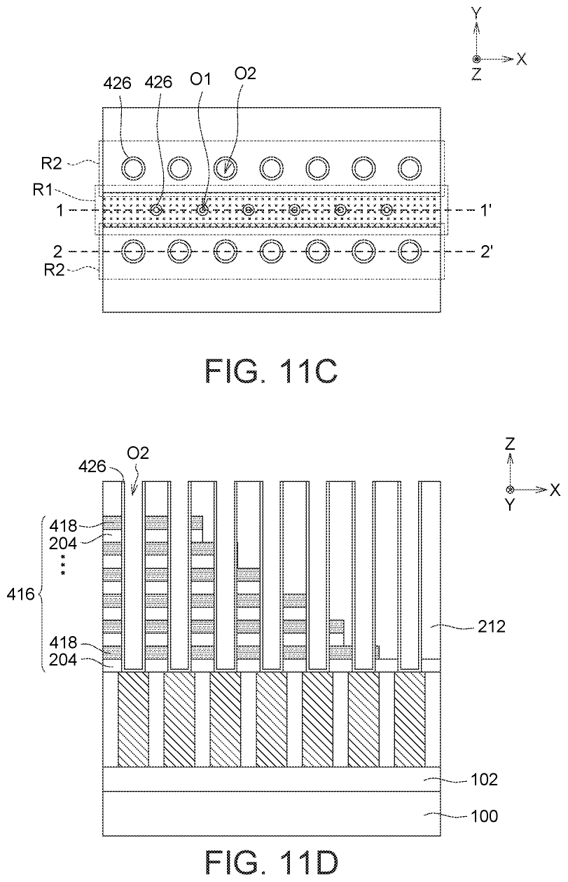

As shown in FIGS. 11A-11D, spacer layers 426 are conformally formed in the first openings O1 and the second openings O2. More specifically, the spacer layers 426 are formed on sidewalls and bottom surfaces of the first openings O1 and the second openings O2. The spacer layers 426 can be formed of oxide. The spacer layers 426 are beneficial for prevention of shortage between conductive layers 202 and the array contacts 208/periphery contacts 210 that will be formed in the following processes.

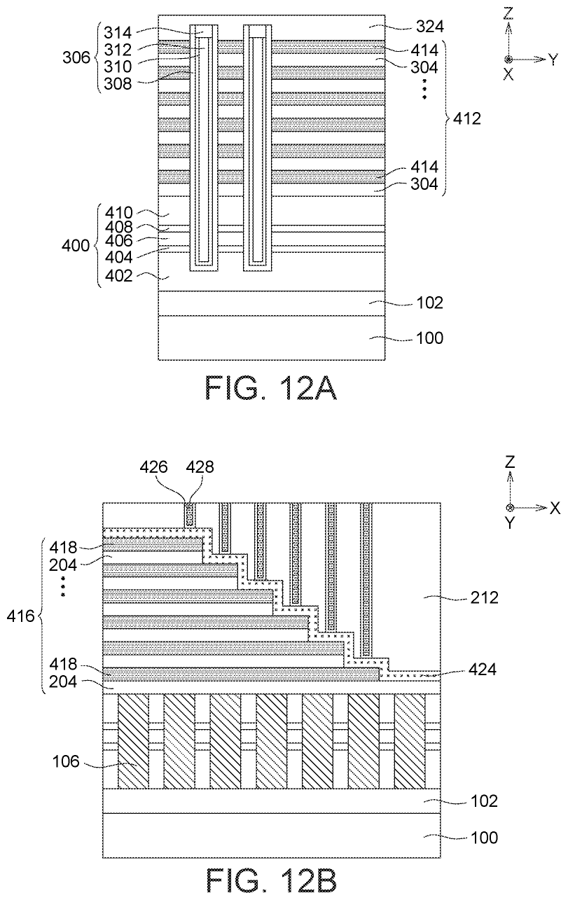

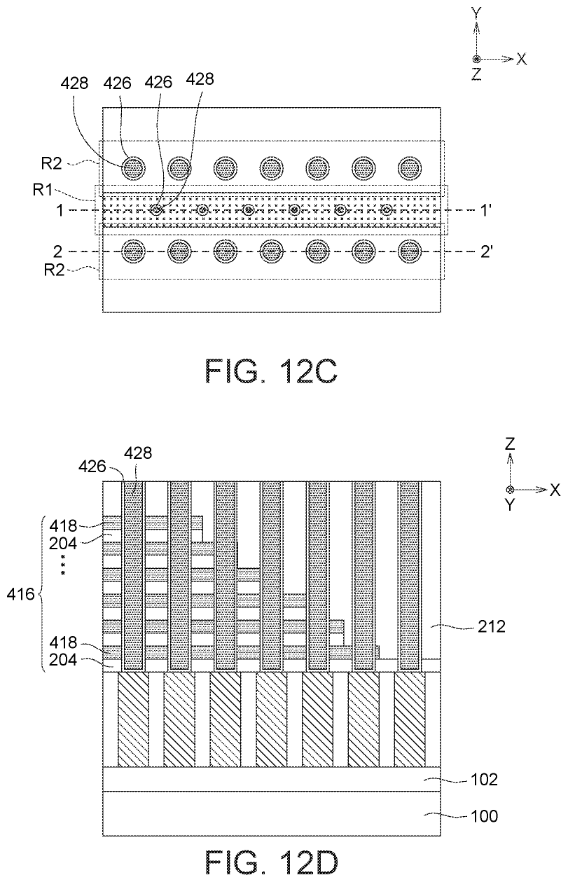

As shown in FIGS. 12A-12D, a sacrificial material 428 is filled into the first openings O1 and the second openings O2. The sacrificial material 428 can be polysilicon.

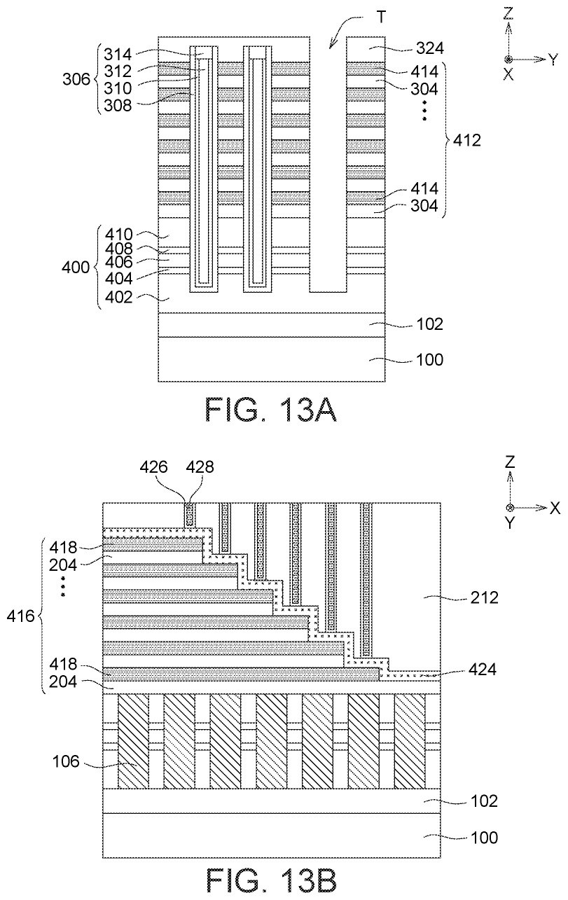

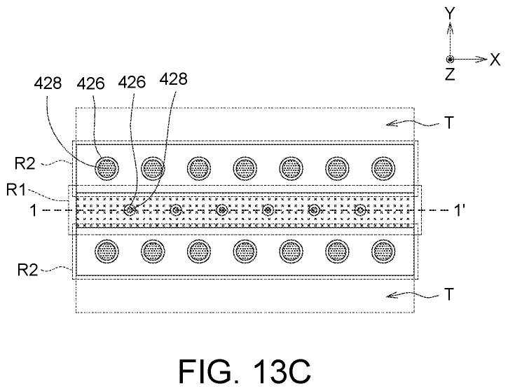

Then, as shown in FIGS. 13A-13C, trenches T are formed through the initial stack 412. The trenches T can extend from the device region to the periphery region outside the array contact defining region R1 and the periphery contact defining region R2, as shown in FIG. 13C.

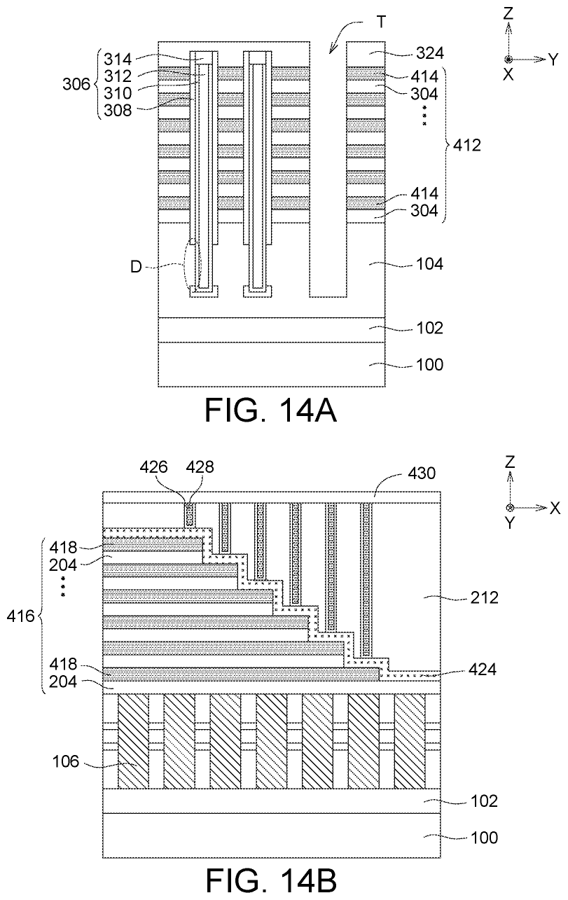

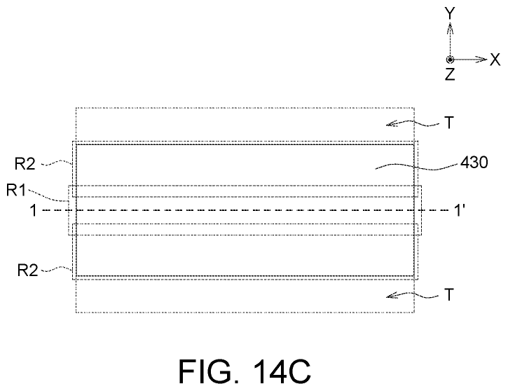

As shown in FIGS. 14A-14C, a mask layer 430 is formed covering the array contact defining region R1 and the periphery contact defining region R2. The mask layer 430 can be formed of oxide. Disconnections D are formed in the memory layers 308 so as to expose the channel layers 310. During the formation of the disconnections D, the first bottom dielectric layer 404, the bottom sacrificial layer 406, and the second bottom dielectric layer 408 are removed, and a conductive material, such as polysilicon, can be filled into a space produced by the removal. The filled conductive material together with the remained first bottom etch stop layer 402 and the second bottom etch stop layer 410 can form the bottom conductive layer 104 as shown in FIGS. 1A-1D. As such, the channel layers 310 of the active structures 306 can be connected by the bottom conductive layer 104.

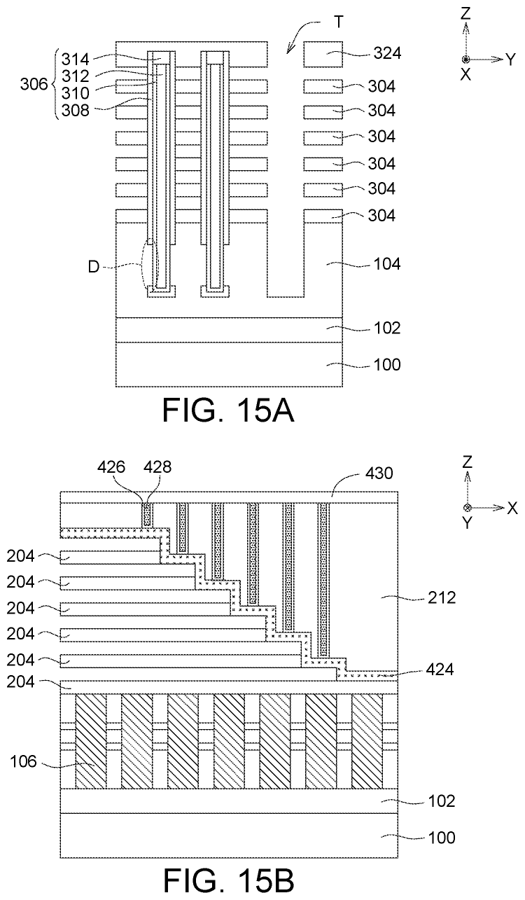

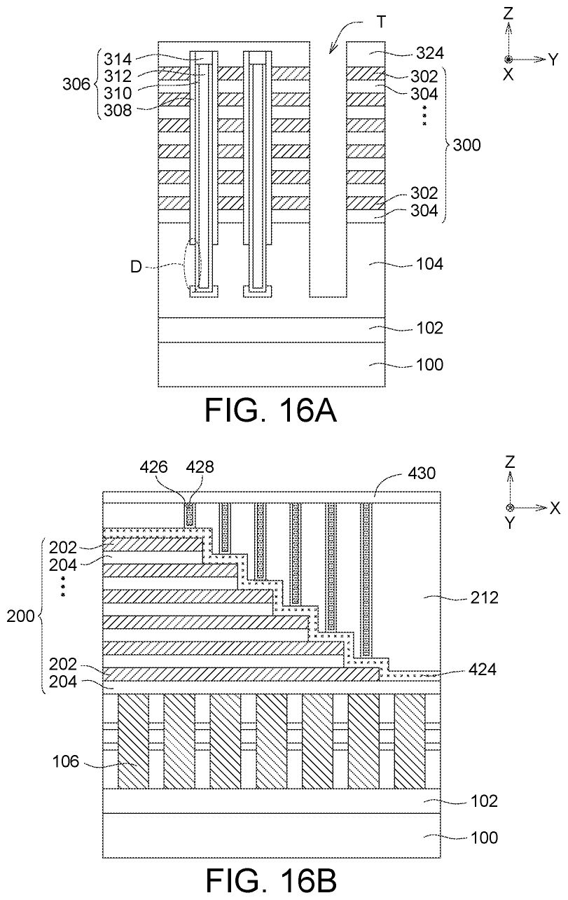

As shown in FIGS. 15A-15B, the sacrificial layers 414 of the initial stack 412 and the sacrificial layers 418 of the initial staircase structure 416 are removed through the trenches T. Then, as shown in FIGS. 16A-16B, conductive layers 202 and conductive layers 302 can be formed in spaces produced by the removal. For example, the conductive layers 202 and conductive layers 302 can be formed by filling a high-k material, a barrier material, and a metal gate material sequentially. As such, the conductive layers 302 can be formed in the initial stack 412 so as to form a stack 300 comprising the conductive layers 302 and the dielectric layers 304 disposed alternately. A plurality of memory cells M can be defined by cross points of the conductive layers 302 in the stack 300 and the active structures 306. The conductive layers 302 can function as word lines and so on. In addition, the sacrificial layers 418 of the initial staircase structure 416 can be replaced with the conductive layers 202 so as to form a staircase structure 200 comprising the conductive layers 202 and the dielectric layers 204 disposed alternately.

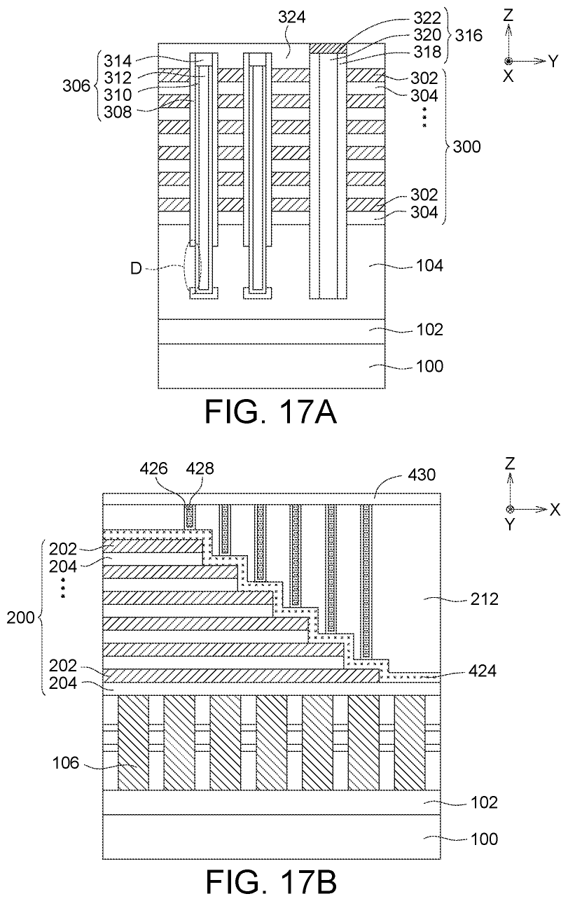

As shown in FIGS. 17A-17B, connecting structures 316 are formed in the trenches T. Each of the connecting structure 316 can comprise a barrier layer 318, a conductive material 320, and a plug 322. The barrier layer 318 is formed as an outermost layer of the connecting structure 316. The barrier layer 318 can be formed of oxide. The conductive material 320 is disposed in a space defined by the barrier layer 318. The conductive material 320 can be polysilicon. The plug 322 is disposed on the conductive material 320. The plug 322 can be formed of metal. The connecting structures 316 can function as connecting structures for a common source line.

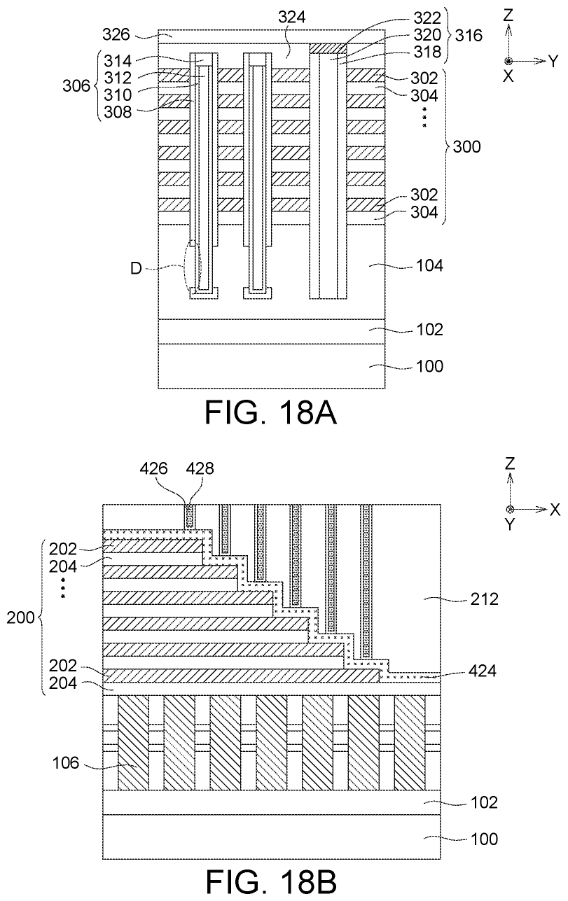

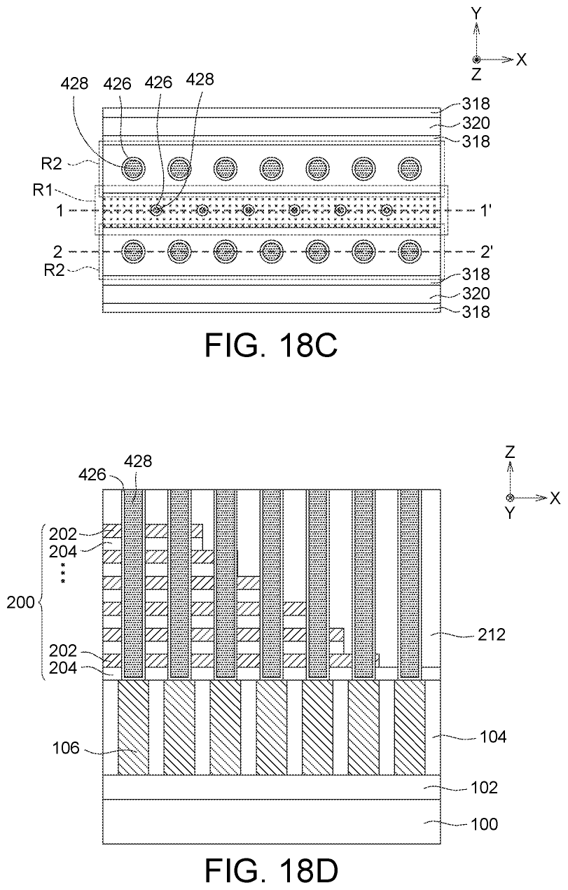

As shown in FIGS. 18A-18D, a top interlayer dielectric layer 326 is formed in the device region. The top interlayer dielectric layer 326 can be formed by depositing oxide on the whole structure, and then removing the oxide in the periphery region. The mask layer 430 is removed.

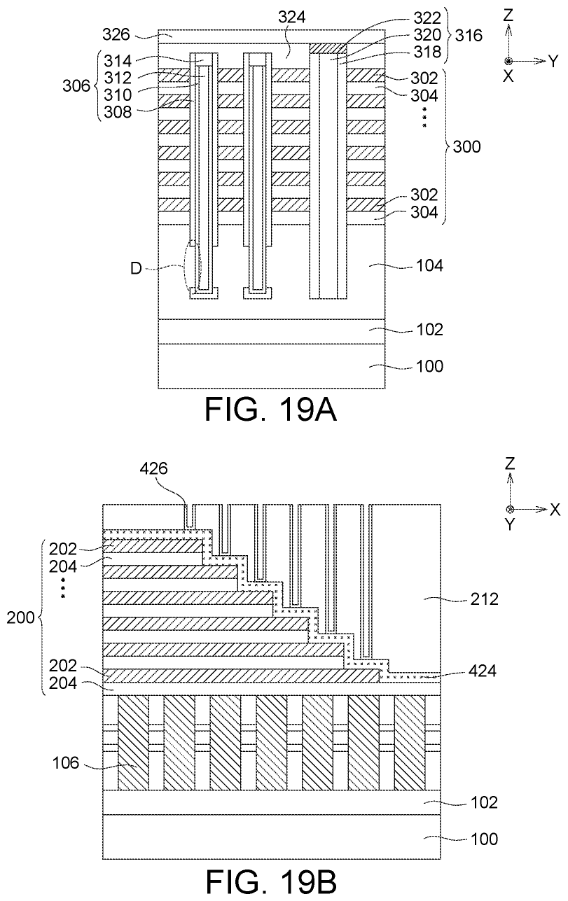

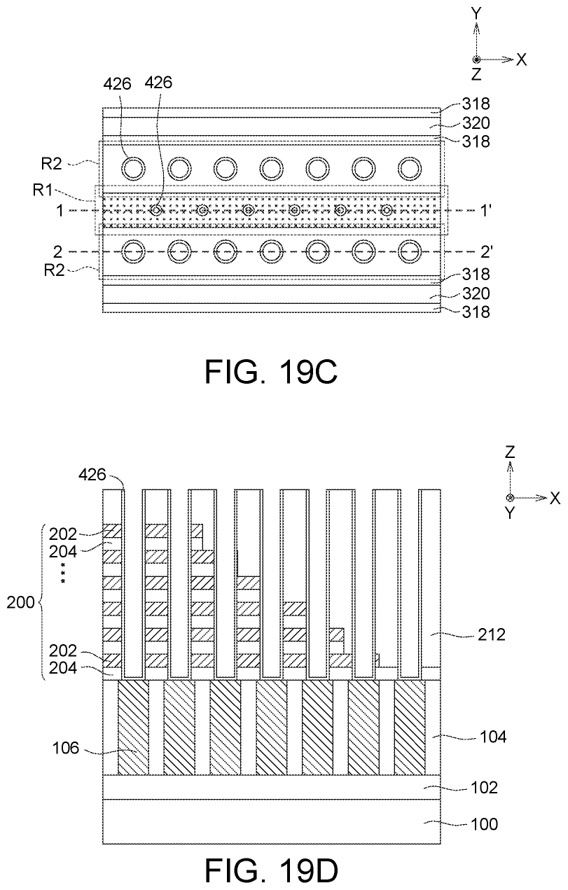

As shown in FIGS. 19A-19D, the sacrificial material 428 is removed. During the removal, the spacer layers 426 can protect the components in the staircase structure 200.

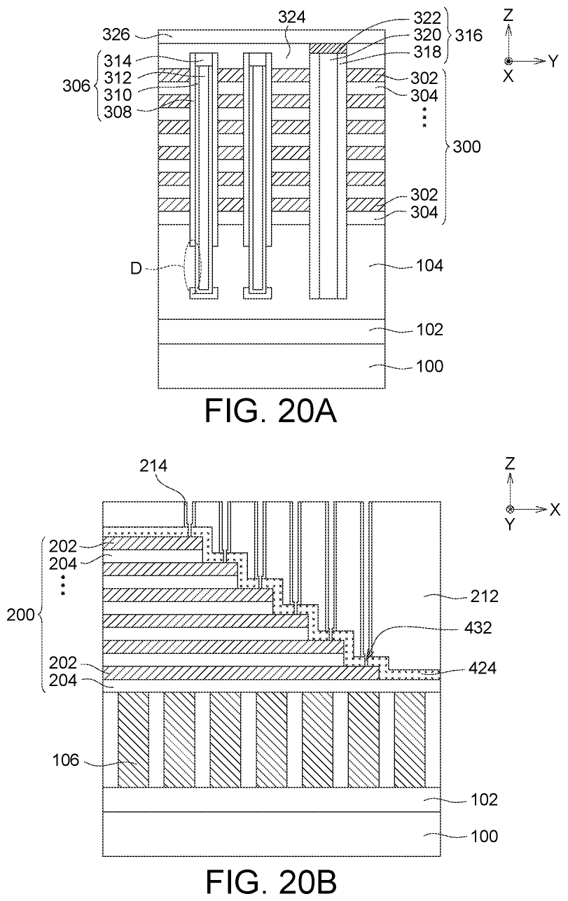

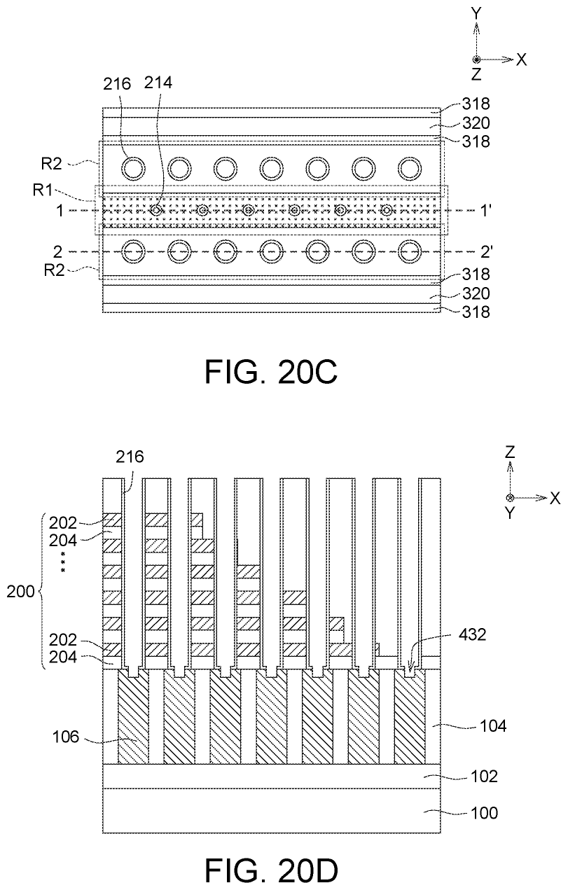

As shown in FIGS. 20A-20D, portions 432 of the spacer layers 426 on the bottom surfaces of the first openings O1 and the second openings O2 are opened, wherein in FIG. 20C, the portions 432 are not show for clarity of the drawing. As such, the conductive layers 202 are exposed from the first openings O1, and the connectors 106 are exposed from the second openings O2. The first spacer layers 214 and the second spacer layers 216 as shown in FIGS. 1A-1D are formed. The opening as shown in FIGS. 20A-20D can be conducted by an etching process. In some embodiments, a cross-sectional area of each of the opened portions 432 is smaller than a cross-sectional area of the corresponding first opening O1 or a cross-sectional area of the corresponding second opening O2.

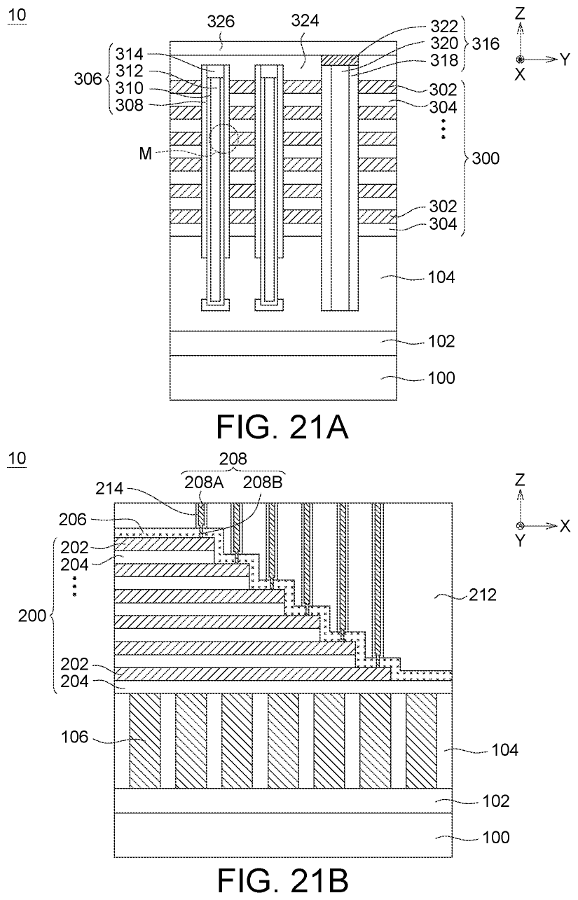

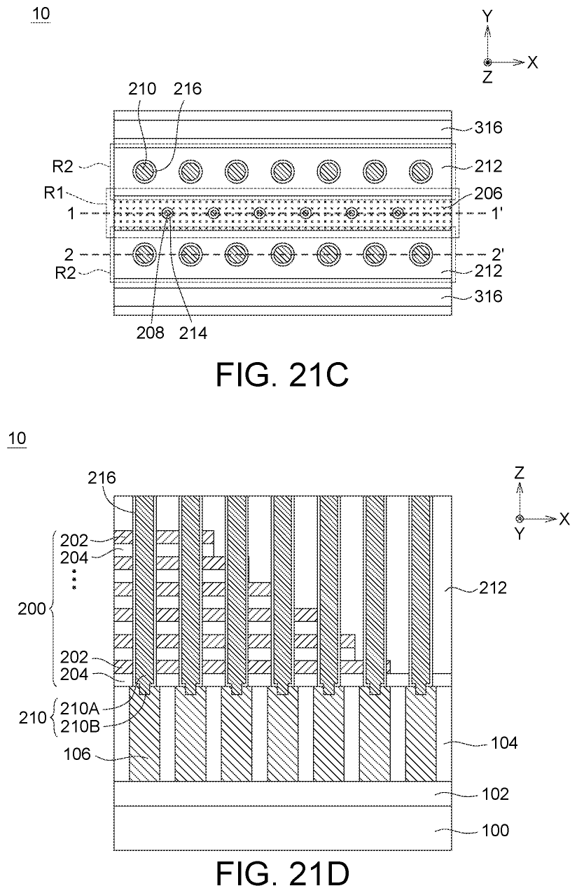

As shown in FIGS. 21A-21D, a conductive material is filled into the first openings O1 and the second openings O2 so as to form a plurality of array contacts 208 and a plurality of periphery contacts 210. Specifically, the array contacts 208 are formed on the staircase structure 200 and through the etch stop layer 206 in the array contact defining region R1, and the periphery contacts 210 are through the staircase structure 200 in the periphery contact defining region R2. The conductive material can be tungsten. A redundant portion of the conductive material can be removed by a planarization process, such as a CMP process. As such, top surfaces of the array contacts 208 and top surfaces of the periphery contacts 210 are flush.

According to the disclosure, the array contacts and the periphery contacts can be formed common processes by using the etch stop layer. As such, the cost produced by deep etch processes can be reduced, and the product yield can be improved. In addition, the periphery contacts in the disclosure can provide the supporting function of conventional dummy active structures. This will be beneficial for the further reduction of the manufacturing cost.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure, having a device region and a periphery region adjacent to the device region, the periphery region comprising an array contact defining region and a periphery contact defining region, the semiconductor structure comprising:
a substrate;
a staircase structure disposed on the substrate in the periphery region, the staircase structure comprising conductive layers and dielectric layers disposed alternately;
an etch stop layer disposed on the staircase structure in the array contact defining region;
a plurality of array contacts disposed on the staircase structure and through the etch stop layer in the array contact defining region; and
a plurality of periphery contacts through the staircase structure in the periphery contact defining region.

2. The semiconductor structure according to claim 1, wherein the etch stop layer is formed of carbon doped silicon nitride.

3. The semiconductor structure according to claim 1, wherein each of the array contacts has a first portion and a second portion under the first portion, and a cross-sectional area of the second portion is smaller than a cross-sectional area of the first portion.

4. The semiconductor structure according to claim 1, wherein each of the periphery contacts has a first portion and a second portion under the first portion, and a cross-sectional area of the second portion is smaller than a cross-sectional area of the first portion.

5. The semiconductor structure according to claim 1, further comprising:
a plurality of first spacer layers surrounding the array contacts; and
a plurality of second spacer layers surrounding the periphery contacts.

6. The semiconductor structure according to claim 1, wherein top surfaces of the array contacts and top surfaces of the periphery contacts are flush.

7. The semiconductor structure according to claim 1, wherein each of the array contacts is surrounded by four periphery contacts that are closest to the array contact among the periphery contacts.

8. The semiconductor structure according to claim 1, wherein the periphery contact defining region comprises two separated regions, and the array contact defining region is between the two separated regions.

9. The semiconductor structure according to claim 1, wherein the conductive layers form treads of the staircase structure.

10. The semiconductor structure according to claim 1, further comprising:
a stack disposed on the substrate in the device region, the stack comprising conductive layers and dielectric layers disposed alternately, wherein the staircase structure disposed in the periphery region is an extension of the stack; and
a plurality of active structures through the stack, each of the active structures comprising:
a memory layer formed as an outermost layer of the active structure;
a channel layer disposed along the memory layer;
a dielectric material disposed in a space defined by the channel layer; and
a contact disposed on the dielectric material;
wherein a plurality of memory cells are defined by cross points of the conductive layers in the stack and the active structures.

11. The semiconductor structure according to claim 10, further comprising:
a bottom conductive layer disposed on the substrate, wherein the memory layers of the active structures have disconnections in the bottom conductive layer such that the channel layers of the active structures are connected by the bottom conductive layer; and
a connecting structure through the stack and stop in the bottom conductive layer, the connecting structure electrically connected with the bottom conductive layer.

12. The semiconductor structure according to claim 1, further comprising:
a circuit layer disposed on the substrate, wherein the staircase structure is disposed on the circuit layer, and the periphery contacts are connected to connectors and further connected to the circuit layer through the connectors.

13. A method for manufacturing a semiconductor structure, wherein the semiconductor structure has a device region and a periphery region adjacent to the device region, and the periphery region comprises an array contact defining region and a periphery contact defining region, and wherein the method comprises:
providing a partially formed structure comprising a substrate and an initial staircase structure on the substrate in the periphery region, wherein the initial staircase structure comprises sacrificial layers and dielectric layers disposed alternately;
forming an etch stop layer on the initial staircase structure in the array contact defining region;
replacing the sacrificial layers of the initial staircase structure with conductive layers so as to form a staircase structure comprising the conductive layers and the dielectric layers disposed alternately; and
forming a plurality of array contacts on the staircase structure and through the etch stop layer in the array contact defining region and forming a plurality of periphery contacts through the staircase structure in the periphery contact defining region.

14. The method according to claim 13, wherein the array contacts and the periphery contacts are formed common processes.

15. The method according to claim 13, comprising:
forming an interlayer dielectric layer on the initial staircase structure and the etch stop layer;
forming first openings through the interlayer dielectric layer and the etch stop layer and landing on stairs of the initial staircase structure and forming second openings through the interlayer dielectric layer and the initial staircase structure;
conformally forming spacer layers in the first openings and the second openings;
filling a sacrificial material into the first openings and the second openings;
after forming the staircase structure, removing the sacrificial material;
opening portions of the spacer layers on bottom surfaces of the first openings and the second openings;
filling a conductive material into the first openings and the second openings so as to form the array contacts and the periphery contacts.

16. The method according to claim 15, wherein a cross-sectional area of each of the opened portions is smaller than a cross-sectional area of the corresponding first opening or a cross-sectional area of the corresponding second opening.

17. The method according to claim 13, wherein the partially formed structure further comprises an initial stack on the substrate in the device region, and the initial stack comprises sacrificial layers and dielectric layers disposed alternately, and wherein the method further comprises:
forming a plurality of active structures through the initial stack, wherein each of the active structures comprises:
a memory layer formed as an outermost layer of the active structure;
a channel layer disposed along the memory layer;
a dielectric material disposed in a space defined by the channel layer; and
a contact disposed on the dielectric material;
forming trenches through the initial stack, wherein the trenches extend from the device region to the periphery region outside the array contact defining region and the periphery contact defining region;
removing the sacrificial layers of the initial stack and the sacrificial layers of the initial staircase structure through the trenches;
forming conductive layers in the initial stack so as to form a stack comprising conductive layers and dielectric layers disposed alternately and forming the staircase structure; and
forming connecting structures in the trenches;
wherein a plurality of memory cells are defined by cross points of the conductive layers in the stack and the active structures.

18. The method according to claim 13, wherein the etch stop layer is formed of carbon doped silicon nitride.

19. The method according to claim 13, wherein top surfaces of the array contacts and top surfaces of the periphery contacts are flush.

20. The method according to claim 13, wherein each of the array contacts is surrounded by four periphery contacts that are closest to the array contact among the periphery contacts.
